(19) United States
(12) Patent Application Publication
(10) Pub. No.: US 2025/0080072 A1
(43) Pub. Date: Mar. 6, 2025

(54) NFC DEMODULATION CIRCUIT

(71) Applicant: STMicroelectronics International N.V., Geneva (CH)

(72) Inventors: Franck MONTAUDON, Meylan (FR); Mounir BOULEMNAKHER, Coublevie (FR); Julien GOULIER, Grenoble (FR)

(73) Assignee: STMicroelectronics International N.V., Geneva (CH)

(21) Appl. No.: 18/812,704

(22) Filed: Aug. 22, 2024

(30) Foreign Application Priority Data
Aug. 29, 2023 (FR) 2309057

(51) Int. Cl. H03F 3/45

(52) U.S. Cl. CPC H03F 3/45475; H03F 2200/451

(57) ABSTRACT

An amplification circuit includes an amplifier circuit (provided by an operational amplifier) that amplifies a signal to be demodulated. A feedback loop of the amplification circuit has a resistance value that is controlled to discretely vary according to a level of an output node of the amplifier circuit. A comparison of the output level with respect to one or a plurality of thresholds, which define out-of-saturation operating ranges of the amplifier circuit, drives selection of the resistance value.

### PRIORITY CLAIM

This application claims the priority benefit of French Application for U.S. Pat. No. 2,309,057, filed on Aug. 29, 2023, the content of which is hereby incorporated by reference in its entirety to the maximum extent allowable by law.

### TECHNICAL FIELD

The present disclosure generally concerns demodulation circuits, particularly demodulation circuits for near-field communication such as the Near Field Communication (NFC) protocol.

### BACKGROUND

In wireless communication devices, particularly near-field communication devices, different types of modulations utilize an amplitude modulation of the radio frequency signal. Two types of demodulation chains are currently used, those with a level detector and those with a rising or falling edge detector, both types comprising amplifiers. In near-field communication devices, the amplitude variations of the signal may be significant and cause a saturation of these demodulation chains. This causes, for example, inaccuracies in the determination of certain parameters of the communication protocol used.

There exists a need to limit the saturation of demodulation chains and to improve the detection of certain communication protocol parameters.

There is a need to overcome all or part of the disadvantages of known demodulation circuits.

### SUMMARY

An embodiment provides an amplification circuit comprising: an amplifier circuit including an operational amplifier and configured to amplify a signal to be demodulated; and a feedback loop having a resistance value which varies discretely according to a level of an output node of said amplifier circuit with respect to one or a plurality of thresholds defining one or a plurality of out-of-saturation operating ranges of the amplifier circuit.

An embodiment provides a demodulation circuit comprising an amplification circuit such as described hereabove.

According to an embodiment, the resistance value of the feedback loop of the amplifier circuit takes a first value when said level is higher than a first threshold or when said level is lower than a second threshold, which is lower than the first threshold.

According to an embodiment, the resistance value of the feedback loop of the amplifier circuit takes a second value when said level is between the first threshold and the second threshold.

According to an embodiment, the resistance value of the feedback loop of the amplifier circuit takes a third value when said level is higher than a third threshold, which is higher than the first threshold, or when said level is lower than a fourth threshold, which is lower than the second threshold.

According to an embodiment, the operational amplifier comprises an inverting input coupled to an input node of the amplifier circuit, and to the output node of the amplifier circuit via the feedback loop.

According to an embodiment, said feedback loop comprises: a first branch coupling the inverting input of the operational amplifier to the output node and formed of a resistive element having the first resistance value; N additional branches, in parallel with the first branch, each formed of a resistive element in series with a switch controlled by a respective control signal, said respective control signal being dependent on a comparison between the level of the output node of said amplifier circuit with respect to a respective operating range from among N out-of-saturation operating ranges of the amplifier circuit, each operating range being defined by thresholds, N being a positive integer; and N comparison circuit configured to generate the respective control signal of each of the N additional branches so as to make the respective switch: non-conductive when the level of the output node of the amplifier circuit is in the respective operating range; and conductive when the level of the output node of the amplifier circuit is outside of said respective operating range.

According to an embodiment, the out-of-saturation operating range of rank N=1 is defined between the first threshold and the second threshold; and the branch of rank N=1 is formed of a resistive element having a fourth resistance value.

According to an embodiment, the out-of-saturation operating range of rank N=2 is defined between the third and fourth thresholds; and the branch of rank N=2 is formed of a resistive element having a fifth resistance value.

According to an embodiment, a first comparison circuit from among the N comparison circuits comprises: a first comparison branch comprising a comparator circuit having a non-inverting input coupled to the output node and an inverting input coupled to a node configured to receive a voltage representative of the first threshold; a second comparison branch comprising a comparator circuit, having a non-inverting input coupled to the output node and an inverting input coupled to a node configured to receive a voltage representative of the second threshold, in series with an inverter circuit; and a logic block configured to perform an OR function based on a signal present on an output node of the comparator circuit of the first branch of the first comparison circuit and another signal present on an output node of the inverter circuit of the second branch of the first comparison circuit; an output of the logic block being the control signal of the switch of the branch of the feedback loop of rank N=1.

According to an embodiment, a second comparison circuit from among the N comparison circuits comprises: a third comparison branch comprising a comparator circuit having a non-inverting input coupled to the output node and an inverting input coupled to a node configured to receive a voltage representative of the third threshold; a fourth comparison branch comprising a comparator circuit, having a non-inverting input coupled to the output node and an inverting input coupled to a node configured to receive a voltage representative of the fourth threshold, in series with another inverter circuit; and another logic block configured to perform an OR function based on a signal present on an output node of the comparator circuit of the third branch of the second comparison circuit and another signal present at the output of the inverter circuit of the fourth branch of the second comparison circuit; an output of said logic block being the signal for controlling the switch of the branch of the feedback loop of rank N=2.

According to an embodiment, the amplification circuit or the demodulation circuit further comprise a flip-flop having: a set input coupled to the output node of the comparator circuit of the first branch of the first comparison circuit; a reset input coupled to the output node of the inverter circuit of the second branch of the first comparison circuit; and an output coupled to an output node of the amplification circuit via an inverter circuit.

According to an embodiment, the inverting input of the operational amplifier is coupled to the input node of the amplifier circuit via a capacitive element in series with an input resistor.

According to an embodiment, the demodulation circuit is of NFC type.

An embodiment provides a near-field communication device comprising the demodulation circuit such as described hereabove.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 is a simplified view of a communication system comprising a first and a second near-field communication devices;

FIG. 2 schematically shows an example of a demodulation circuit of a device of FIG. 1;

FIG. 3 shows a timing diagram of the operation of the circuit of FIG. 2;

FIG. 4 schematically shows an example of a demodulation circuit of a device of FIG. 1;

FIG. 5 shows a timing diagram of the operation of the circuit of FIG. 4;

FIG. 6 schematically shows an example of a demodulation circuit of the device of FIG. 1;

FIG. 7 show a timing diagram of the operation of the circuit of FIG. 6.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for the understanding of the described embodiments have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “edge”, “back”, “top”, “bottom”, “left”, “right”, etc., or relative positions, such as terms “above”, “under”, “upper”, “lower”, etc., or to terms qualifying directions, such as terms “horizontal”, “vertical”, etc., it is referred, unless specified otherwise, to the orientation of the drawings.

Unless specified otherwise, the expressions “about”, “approximately”, “substantially”, and “in the order of” signify plus or minus 10%, preferably of plus or minus 5%.

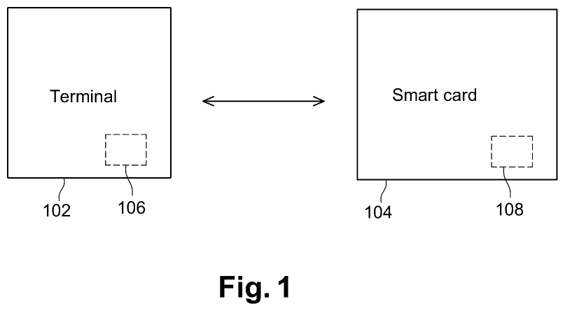

FIG. 1 shows a simplified view of a communication system comprising a first 102 (Terminal) near-field communication device and a second 104 (Smart card) near-field communication device.

In the rest of the disclosure, a near-field communication device is understood to mean an electronic device integrating at least one near-field communication circuit implementing protocols of the NFC (“Near-Field Communication”) forum or contactless system protocols complying with ISO standard 14443. Reference to near field refers to, and is understood as, an electromagnetic field having a limited range from a few centimeters to approximately 2 meters according to the protocols used.

First device 102 is, for example, in card reader mode and second device 104 in card emulation mode. First device 102 is, for example, configured to activate second device 104 by the emission of a modulated magnetic field with the reading in return of another modulated radio frequency signal containing information of the card.

First and second device 102, 104 each comprise, for example, a demodulation circuit 106, 108 to demodulate the signals issued by the other device.

The type of modulation used by these devices to communicate in radio frequency is, for example, an amplitude modulation over 1 bit. Different codings such as the modified Miller, Manchester, or also NRZ code may further be used as well as a modulation rate, for example from a few percent to 100%. The exchanged signals may also take different forms to ease the detection of rising or falling edges. The amplitude of the radio frequency field received by the second device 104 may significantly vary, for example, according to the distance separating them or according to the output level of first device 102.

Demodulation circuits 106, 108 are, for example, of level detection or edge detection type.

Level detectors compare the signal with a threshold. When the signal exceeds the threshold, a high level is detected and, when the signal falls under the threshold, a low level is detected.

Edge detectors use, for example, the comparison of the derivative of the signal with respect to two high and low thresholds.

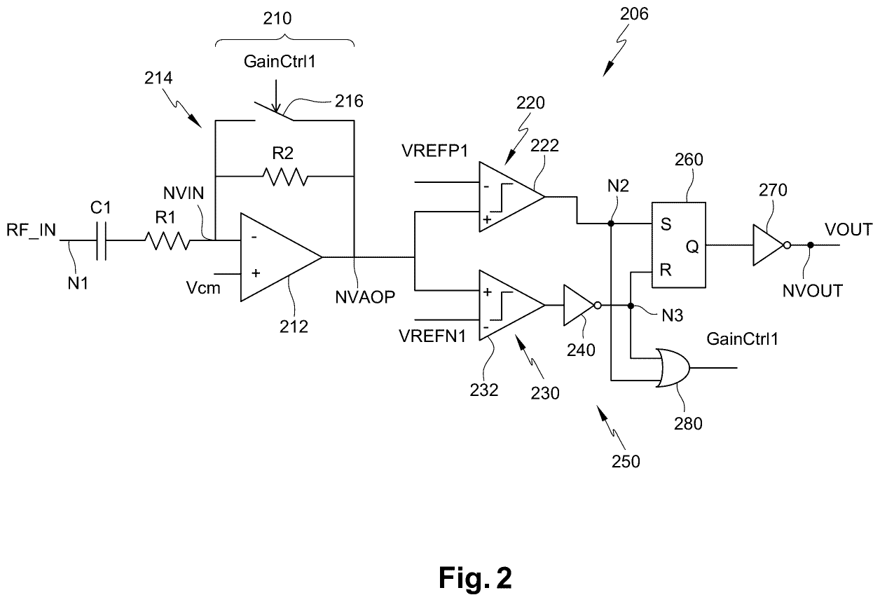

FIG. 2 schematically shows an example of a demodulation circuit 206 of a device 102, 104 of FIG. 1.

In the shown example, demodulation circuit 206 comprises at its input a high-pass radio frequency filter formed of a capacitive element C1 in series with a resistor R1. This filter for example enables to provide a derivative of input signal RF_IN. The filter couples an input node (N1) of the circuit to an input node (NVIN) of an amplifier circuit 210. Input node N1 is configured to receive a radio frequency signal RF_IN to be demodulated. Amplifier circuit 210 comprises an operational amplifier 212 having an inverting input (−) coupled, preferably connected, to input node NVIN. A non-inverting input (+) is configured to be coupled, preferably connected, to a power supply rail of a voltage Vcm. Input node NVIN is coupled, preferably connected, to an output node (NVAOP) of amplifier circuit 210 via a feedback loop 214. Feedback loop 214 comprises a first branch and a second branch in parallel and both coupling output node NVAOP to input node NVIN. The first branch comprises a switch 216 controlled by a first gain control signal (GainCtrl1). The second branch comprises a resistor (R2). The ratio of resistors R2 and R1 enables to set the gain of amplifier circuit 210.

In the shown example, demodulation circuit 206 further comprises a first signal level comparison circuit 250. First comparison circuit 250 comprises a first branch coupling node NVAOP to a node N2 and a second branch coupling node NVAOP to another node N3. First branch comprises a voltage comparator circuit 220. Comparator circuit 220 comprises an operational amplifier 222 having an inverting input (−) configured to be coupled, preferably connected, to a voltage rail VREFP1 defining a first threshold. Operational amplifier 222 comprises a non-inverting input (+) configured to be coupled, preferably connected, to node NVAOP. An output of amplifier 222 is coupled, preferably connected, to node N2. When the level of the signal on node NVAOP is higher than VREFP1, then amplifier 222 returns a high-level signal onto node N2. In the opposite case, a low-level signal is returned onto node N2.

In the shown example, the second branch of first comparison circuit 250 comprises a voltage comparator circuit 230. Comparator circuit 230 comprises an operational amplifier 232 having an inverting input (−) configured to be coupled, preferably connected, to a voltage rail VREFN1 defining a second threshold. Operational amplifier 232 further comprises a non-inverting input (+) configured to be coupled, preferably connected, to node NVAOP. An output of amplifier 232 is coupled to node N3 via an inverter circuit 240. When the level of the signal on node NVAOP is higher than VREFN1, then amplifier 232 returns a high-level signal which becomes low on node N3 after inversion. In the opposite case, a high-level signal is returned onto node N3.

The two thresholds VREFP1 and VREFN1 define together an area where amplifier circuit 210 is not saturated. Above VREFP1 and below VREFN1, amplifier circuit is, for example, saturated.

In the shown example, demodulation circuit 206 further comprises a logic circuit 280 configured to perform an “OR” function based on the signals present on nodes N2 and N3. The resulting signal is gain control signal GainCtrl1. When the signal on node NVAOP is greater than VREFP1 and VREFN1, then signal GainCtrl1 is at a high level, when the signal on node NVAOP is lower than VREFP1 but higher than VREFN1, then signal GainCtrl1 is at a low level, and when the signal on node NVAOP is lower than VREFP1 and lower than VREFN1, then signal GainCtrl1 is at a high level. When signal GainCtrl1 is at a high level, this implies, for example, that switch 216 is conductive, and when signal GainCtrl1 is at a low level this implies, for example, that switch 216 is non-conductive. When switch 216 is non-conductive, this implies that the gain of amplifier circuit 210 is R2/R1 and when switch 216 is conductive, this implies that the gain of amplifier circuit 210 is zero, that is, node NVIN is directly connected to node NVAOP.

In the shown example, demodulation circuit 206 further comprises a flip-flop 260 having a set input(S) coupled to node N2, a reset input (R) coupled to node N3, and an output (Q) coupled to an output node (NVOUT) of the demodulation circuit via an inverter circuit 270.

The circuit of FIG. 2 allows an automatic control of the amplification gain of the signal (AGC, Automatic Gain Control) by automatically and discretely varying the gain from a zero value (case where switch 216 is on, that is, conductive) to a value R2/R1 (case where switch 216 is off, that is, non-conductive) and this, according to the level of the signal of node NVAOP with respect to references VREFP1 and VREFN1.

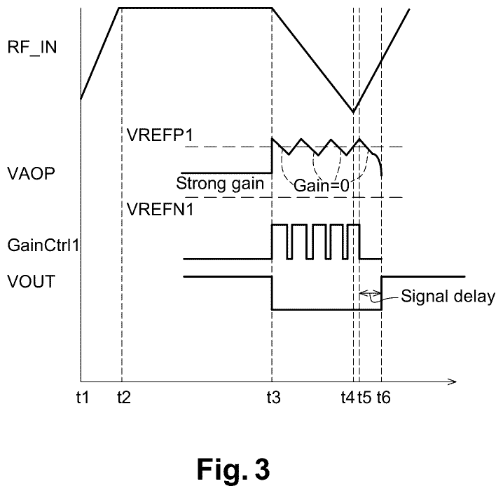

FIG. 3 shows a timing diagram of the operation of the circuit of FIG. 2. More particularly, FIG. 3 shows input signal RF_IN, the voltage VAOP at node NVAOP, as well as signals GainCtrl1 and VOUT.

Between a time t1 and a time t2 subsequent to t1, the received signal RF_IN increases linearly.

Between time t2 and a time t3 subsequent to t2, signal RF_IN stabilizes at a high level. Signal VAOP is between voltage levels NVREFP1 and NVREFN1, which implies that signal GainCtrl1 is at a low level, for example 0, and the gain is in this case high (Strong gain) and proportional to R2/R1. Over this time period, signal VOUT remains stable since there is no change in signal RF_IN.

Between time t3 and a time t4 subsequent to t3, signal RF_IN linearly decreases. Just after time t3, signal VAOP abruptly increases and exceeds voltage threshold VREFP1. Signal GainCtrl1 then switches to a high level, which automatically switches the gain to a zero value (Gain=0) and signal VOUT switches to a low level. Amplifier 212 is then shorted and the output voltage tends towards the common mode between VREFP1 and VREFN1. Signal VAOP then linearly decreases until it passes under threshold voltage VREFP1. At that time, signal GainCtrl1 switches back to a low level. As signal RF_IN keeps on decreasing, signal VAOP, which is amplified again with ratio R2/R1, linearly rises to exceed threshold VREFP1 again. When this threshold has been exceeded, signal GainCtrl1 switches back to a high level, which lowers back VAOP and so on. Signal VAOP thus oscillates in sawtooth fashion around threshold value VREFP1 and signal GainCtrl1 correspondingly alternates between high and low levels.

Between time t4 and a time t6 subsequent to t4, signal RF_IN rises linearly. Signal VOUT remains at a low level as long as signal VAOP does not decrease below threshold VREFN1.

Between time t4 and a time t5 between time t4 and time t6, signal VAOP increases for a last time above threshold VREFP1 before decreasing back between time t5 and time t6 under threshold VREFP1 while remaining above VREFN1.

Between time t5 and time t6, signal GainCtrl1 switches to a low level and remains at a low level until signal VAOP passes under threshold VREFN1 at time t6. Signal VOUT then switches from the low state to the high state. The variations of signal RF_IN are thus digitized.

The period (Signal Delay) between time t5 and time t6 corresponds to a delay of detection of the signal variation. This is due to the fact that the variations of signal VAOP are not visible when amplifier 212 is shorted. The determination of the frame delay time (FDT), which is a fundamental parameter of NFC and ISO protocols 14443, is thereby altered. Another disadvantage of the example of FIG. 2 is due to the fact that, when amplifier 212 is shorted, this generates a signal discontinuity and the stability of the circuit is impacted.

The described embodiments provide a demodulation circuit NFC comprising an amplifier circuit configured to amplify a signal to be demodulated with a gain, different from zero, having a value discretely varying according to a level of the output node of the amplifier circuit with respect to one or a plurality of thresholds defining one or a plurality of out-of-saturation operating ranges of the amplifier.

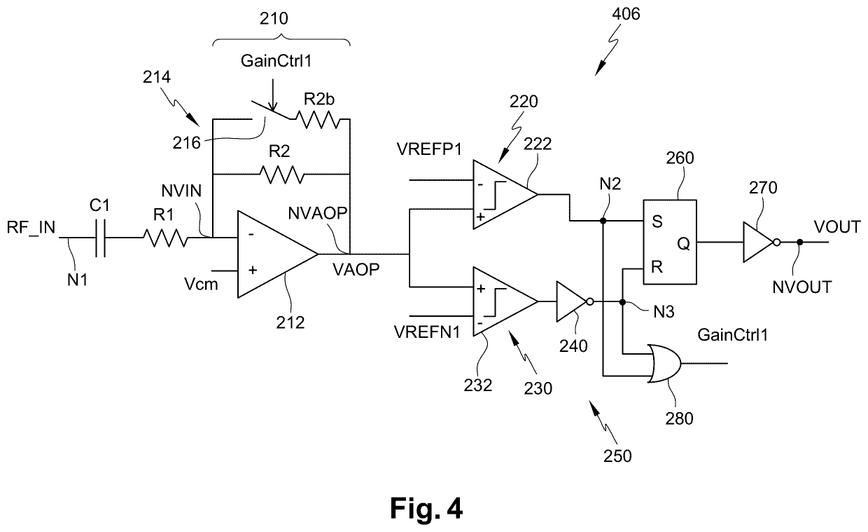

FIG. 4 schematically shows an example of a demodulation circuit 406 of one of the devices 102, 104 of FIG. 1 according to an embodiment.

In the shown example, demodulation circuit 406 is similar to the demodulation circuit 206 of FIG. 2 except that an additional resistor R2b is added in the first branch of feedback loop 214 to connect switch 216 to node NVAOP or to connect switch 216 to node NVIN. Resistor R2b enables to define another non-zero gain level of amplifier circuit 210 than that obtained with the branch comprising resistor R2.

Conversely to the example of FIG. 2, amplifier 210 is not shorted when switch 216 is controlled to be conductive. The gain of amplifier circuit 210 thus discretely varies between R2/R1 when signal NVAOP is between VREFP1 and VREFN1, and (R2b·R2)/(R1(R2+R2b)) when signal NVAOP is above VREFP1 or below VREFN1.

In the example of FIG. 4, the gain area defined between VREFP1 and VREFN1 is an area outside of the saturation of amplifier 212 corresponding to a high gain and the areas located above VREFP1 and under VREFN1 are areas outside of the saturation of amplifier 212 corresponding to a lower but non-zero gain.

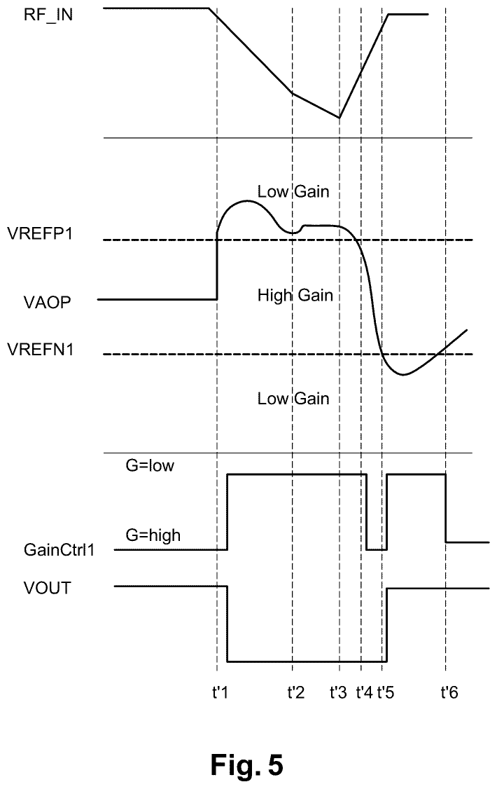

FIG. 5 shows a timing diagram of the operation of the circuit of FIG. 4.

More particularly, FIG. 5 shows signals RF_IN, VAOP, GainCtrl1, and VOUT.

Before a time t′1, signal RF_IN is at a high level, signal VAOP is stable and between VREFP1 and VREFN1, Gaintrl1 is in a low state (G=high), and output VOUT is in a high state.

From a time t′1, signal RF_IN decreases with a first slope until a time t′2. Signal RF_IN then decreases until a time t′3 with a lower slope.

Between times t′1 and t′2, signal VAOP increases above threshold VREFP1, which places GainCtrl1 at a high level (G=low) and VOUT switches to a low level.

Between times t′2 and t′3, signal VAOP remains above threshold VREFP1, which places GainCtrl1 at a high level (G=low), and VOUT remains at a low level.

At time t′3 and until a time t′5, signal RF_IN changes direction and linearly increases.

Between time t′3 and a time t′4, signal VAOP decreases to pass under threshold VREFP1, which switches signal GainCtrl1 to a low state.

Between time t′4 and time t′5, signal VAOP keeps on decreasing and signal GainCtrl1 remains in a low state.

At time t′5, signal VAOP decreases under threshold VREFN1, which switches signals GainCtrl1 and VOUT to a high state.

After time t′5, signal RF_IN stabilizes at a high state, signal VAOP rises back and passes above VREFN1 again at a time t′6, which switches GainCtrl1 to a low state.

The example of FIG. 4 enables to form a hysteresis where output signal VOUT switches state only after the two thresholds VREFP1 and VREFN1 have been crossed in one direction or in the other.

When signal GainCtrl1 is at a low level, the gain is high (High Gain) to increase the sensitivity. When signal GainCtrl1 is at a high level, the gain is low (Low Gain) to limit the output dynamics and prevent the saturation of amplifier 212 while maintaining a certain gain level to allow the detection of the signal variations. In other words, the use of a non-zero gain in the area where GainCtrl1 is at a high level enables not to be in saturation while increasing the accuracy of detection of the signal variations.

In the example of FIG. 5, thresholds VREFP1 and VREFN1 define an out-of-saturation operating range of amplifier 212 but values slightly higher than VREFP1 and slightly lower than VREFN1 also define an out-of-saturation operation due to the action of the non-zero gain.

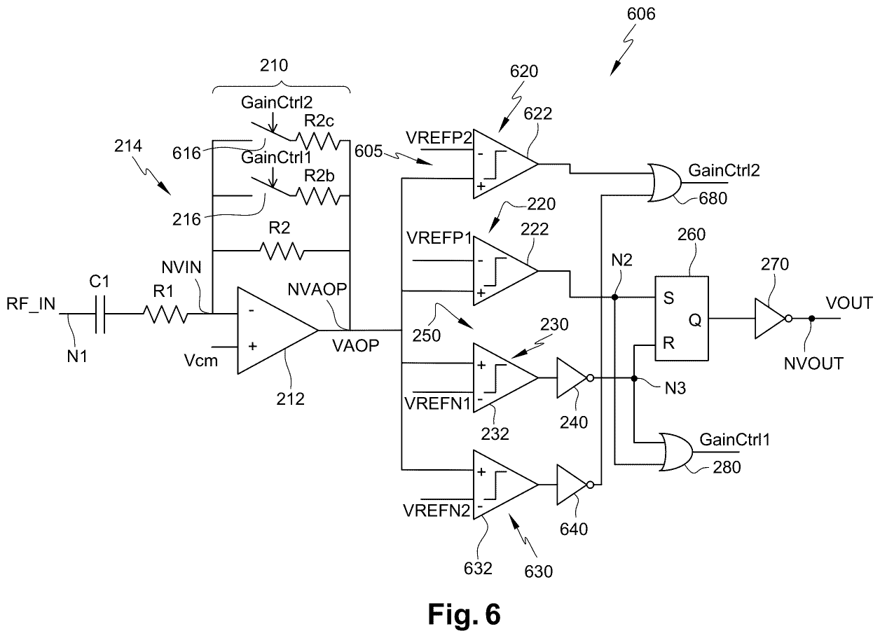

FIG. 6 schematically shows an example of a demodulation circuit of the device of FIG. 1 according to another embodiment.

The demodulation circuit 606 of FIG. 6 is similar to that of FIG. 4, except that the feedback loop 214 of amplifier circuit 210 comprises a third branch comprising a switch 616, controlled by a signal (GainCtrl2), in series with a resistor (R2c). The third branch couples node NVIN to node NVAOP. Resistor R2c enables to obtain a gain level different from the gains obtained with the branches comprising resistors R2 and R2b when they are respectively activated.

The demodulation circuit 606 of FIG. 6 also differs from that of FIG. 4 in that demodulation circuit 206 further comprises a second signal level comparison circuit 650. Second comparison circuit 650 comprises a third branch coupling node NVAOP to an input of a logic circuit 680 configured to perform the “OR” function. Second comparison circuit 650 comprises a fourth branch coupling node NVAOP to another input of logic circuit 680. The third branch comprises a voltage comparator circuit 620. Comparator circuit 620 comprises an operational amplifier 622 having an inverting input (−) configured to be coupled, preferably connected, to a voltage rail VREFP2 higher than VREFP1 and defining a third threshold. Operational amplifier 622 further comprises a non-inverting input (+) configured to be coupled, preferably connected, to node NVAOP. An output of amplifier 622 is coupled, preferably connected, to one of the inputs of logic circuit 680. When the level of the signal on node NVAOP is higher than VREFP2, then amplifier 622 returns a high-level signal on this input of logic circuit 680. In the opposite case, a low-level signal is returned.

In the shown example, the fourth branch of second comparison circuit 650 comprises a voltage comparator circuit 630. Comparator circuit 630 comprises an operational amplifier 632 having an inverting input (−) configured to be coupled, preferably connected, to a voltage rail VREFN2, lower than VREFN1 and defining a fourth threshold. Operational amplifier 632 further comprises a non-inverting input (+) configured to be coupled, preferably connected, to node NVAOP. An output of amplifier 632 is coupled to another of the inputs of logic circuit 680 via an inverter circuit 640. When the level of the signal on node NVAOP is lower than threshold VREFN2, then amplifier 632 returns a high-level signal which becomes low at the input of logic circuit 680 after inversion. In the opposite case, a low-level signal is returned. The output of logic circuit 680 is control signal GainCtrl2.

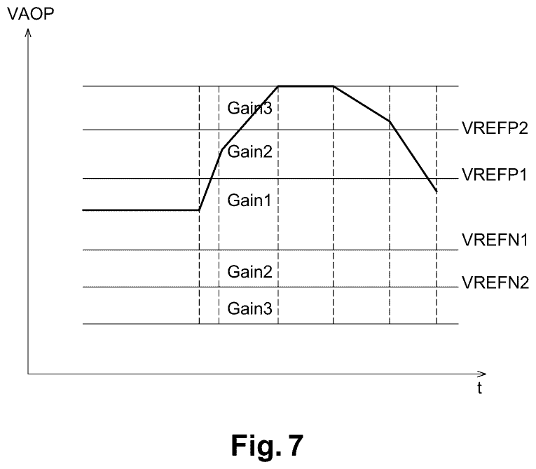

FIG. 7 shows a timing diagram of the operation of the circuit of FIG. 6.

The operation of the circuit of FIG. 6 is similar to that of FIG. 4 except that, when signal VAOP exceeds thresholds VREFP1 and VREFP2, or falls below thresholds VREFN1 and VREFN2, switch 616 is activated by signal GainCtrl2 and the gain of amplifier circuit 210 becomes equal to (R2b·R2·R2c)/(R1((R2·R2c)+(R2b·R2c)+(R2b·R2))). As signal VAOP crosses successive thresholds, its slope is attenuated by the discrete lowering of the gain of amplifier circuit 210 to remain in an out-of-saturation operating area.

Various embodiments and variants have been described. Those skilled in the art will understand that certain features of these various embodiments and variants may be combined, and other variants will occur to those skilled in the art. In particular, even though the examples of FIGS. 4 and 6 particularly show a feedback loop 214 with respectively two and three branches, it is possible for those skilled in the art to implement more branches in parallel, each comprising a switch and a resistor. The switch of each of these additional branches will be controlled by a signal originating from the comparison of signal VAOP with one or a plurality of thresholds. In this case, other additional comparator circuits, such as circuits 220, 230, 620, 630, may be implemented and associated with one or a plurality of logic circuits such as circuits 280 or 680.

Finally, the practical implementation of the described embodiments and variants is within the abilities of those skilled in the art based on the functional indications given hereabove. In particular, as to the type of flip-flop 260 where other types of flip-flops may be used instead of flip-flop 260. Those skilled in the art may also implement comparator circuits 220, 230, 620, and 630 according to their knowledge. On the other hand, those skilled in the art may implement feedback loop 214 differently, provided for its resistance to vary discretely, while being non-zero, according to thresholds.

Those skilled in the art may implement the described demodulation circuits for radio frequency communication types other than the NFC type.

1. An amplification circuit, comprising:
an amplifier circuit including an operational amplifier, said amplifier circuit configured to amplify a signal to be demodulated; and
a feedback loop having a resistance value discretely varying according to a level of an output node of said amplifier circuit with respect to one or a plurality of thresholds defining one or a plurality of out-of-saturation operating ranges of the amplifier circuit.

2. The amplification circuit according to claim 1, wherein the resistance value of the feedback loop of the amplifier circuit is controlled to have a first resistance value when said level is higher than a first threshold or when said level is lower than a second threshold, where the second threshold is lower than the first threshold.

3. The amplification circuit according to claim 2, wherein the resistance value of the feedback loop of the amplifier circuit is controlled to have a second resistance value when said level is between the first threshold and the second threshold.

4. The amplification circuit according to claim 3, wherein the resistance value of the feedback loop of the amplifier circuit is controlled to have a third resistance value when said level is higher than a third threshold, wherein the third threshold is higher than the first threshold, or when said level is lower than a fourth threshold, wherein the fourth threshold is lower than the second threshold.

5. The amplification circuit according to claim 1, wherein the operational amplifier comprises an inverting input coupled to an input node of the amplifier circuit and coupled to the output node of the amplifier circuit via the feedback loop.

6. The amplification circuit according to claim 5, wherein said feedback loop comprises:
a first branch coupling the inverting input of the operational amplifier to the output node, said first branch including a resistive element having a first resistance value;
N additional branches coupled in parallel with the first branch, wherein each additional branch includes a resistive element in series with a switch controlled by a respective control signal, N being a positive integer;
said respective control signal being dependent on a comparison between the level of the output node of said amplifier circuit with respect to a respective operating range from among N out-of-saturation operating ranges of the amplifier circuit, each operating range being defined by thresholds; and
N comparison circuits configured to generate a respective control signal for each of the N additional branches to make the respective switch:
non-conductive when the level of the output node of the amplifier circuit is in the respective operating range; and
conductive when the level of the output node of the amplifier circuit is outside of said respective operating range.

7. The amplification circuit according to claim 6:
wherein the resistance value of the feedback loop of the amplifier circuit is controlled to have a first resistance value when said level is higher than a first threshold or when said level is lower than a second threshold, where the second threshold is lower than the first threshold; and
wherein the N=1 out-of-saturation operating range is defined between the first threshold and the second threshold and the N=1 branch is formed of a resistive element having a fourth resistance value.

8. The amplification circuit according to claim 7, further comprising a flip-flop having:
a set input coupled to the output node of the comparator circuit of the first branch of the first comparison circuit;
a reset input coupled to the output node of the inverter circuit of the second branch of the first comparison circuit; and
an output coupled to an output node of the amplification circuit via an inverter circuit.

9. The amplification circuit according to claim 7, wherein a first comparison circuit from among the N comparison circuits comprises:
a first comparison branch comprising a comparator circuit having a non-inverting input coupled to the output node and an inverting input coupled to a node configured to receive a voltage representative of the first threshold;
a second comparison branch comprising a comparator circuit, having a non-inverting input coupled to the output node and an inverting input coupled to a node configured to receive a voltage representative of the second threshold, in series with an inverter circuit; and
a logic block configured to perform an OR function based on a signal present on an output node of the comparator circuit of the first branch of the first comparison circuit and another signal present on an output node of the inverter circuit of the second branch of the first comparison circuit;
an output of the logic block being the control signal of the switch of the N=1 branch of the feedback loop.

10. The amplification circuit according to claim 9:
wherein the resistance value of the feedback loop of the amplifier circuit is controlled to have a second resistance value when said level is between the first threshold and the second threshold;
wherein the resistance value of the feedback loop of the amplifier circuit is controlled to have a third resistance value when said level is higher than a third threshold, wherein the third threshold is higher than the first threshold, or when said level is lower than a fourth threshold, wherein the fourth threshold is lower than the second threshold; and
wherein the N=2 out-of-saturation operating range is defined between the third and fourth thresholds and the N=2 branch is formed of a resistive element having a fifth resistance value.

11. The amplification circuit according to claim 10, wherein a first comparison circuit from among the N comparison circuits comprises:
a first comparison branch comprising a comparator circuit having a non-inverting input coupled to the output node and an inverting input coupled to a node configured to receive a voltage representative of the first threshold;
a second comparison branch comprising a comparator circuit, having a non-inverting input coupled to the output node and an inverting input coupled to a node configured to receive a voltage representative of the second threshold, in series with an inverter circuit; and
a logic block configured to perform an OR function based on a signal present on an output node of the comparator circuit of the first branch of the first comparison circuit and another signal present on an output node of the inverter circuit of the second branch of the first comparison circuit;
an output of the logic block being the control signal of the switch of the N=1 branch of the feedback loop.

12. The amplification circuit according to claim 11, wherein a second comparison circuit from among the N comparison circuits comprises:
a third comparison branch comprising a comparator circuit having a non-inverting input coupled to the output node and an inverting input coupled to a node configured to receive a voltage representative of the third threshold;
a fourth comparison branch comprising a comparator circuit, having a non-inverting input coupled to the output node and an inverting input coupled to a node configured to receive a voltage representative of the fourth threshold, in series with another inverter circuit; and
another logic block configured to perform an OR function based on a signal present on an output node of the comparator circuit of the third branch of the second comparison circuit and another signal present at the output of the inverter circuit of the fourth branch of the second comparison circuit;
an output of said logic block being the signal for controlling the switch of the N=2 branch of the feedback loop.

13. The amplification circuit according to claim 12, further comprising a flip-flop having:
a set input coupled to the output node of the comparator circuit of the first branch of the first comparison circuit;
a reset input coupled to the output node of the inverter circuit of the second branch of the first comparison circuit; and
an output coupled to an output node of the amplification circuit via an inverter circuit.

14. The amplification circuit according to claim 5, wherein the inverting input of the operational amplifier is coupled to the input node of the amplifier circuit via a capacitive element in series with an input resistor.

15. A demodulation circuit comprising the amplification circuit according to claim 1.

16. The demodulation circuit according to claim 15, wherein the demodulation circuit is of NFC type.

17. A near-field communication device comprising the demodulation circuit according to claim 15.

18. An amplification circuit, comprising:
an amplifier circuit configured to amplify a signal to be demodulated; and
a feedback loop coupled between and input node and output node of the amplifier circuit;
wherein the feedback loop has a resistance value discretely varying according to a level at the output node of said amplifier circuit with respect to one or a plurality of thresholds defining one or a plurality of out-of-saturation operating ranges of the amplifier circuit;
wherein the resistance value of the feedback loop of the amplifier circuit is controlled to have a first resistance value when said level is higher than a first threshold or when said level is lower than a second threshold, where the second threshold is lower than the first threshold; and
wherein said feedback loop comprises:
a first branch coupling the input node of the amplifier circuit to the output node, said first branch including a resistive element having a first resistance value;
N additional branches coupled in parallel with the first branch, wherein each additional branch includes a resistive element in series with a switch controlled by a respective control signal, N being a positive integer greater than two;
said respective control signal being dependent on a comparison between the level of the output node of said amplifier circuit with respect to a respective operating range from among N out-of-saturation operating ranges of the amplifier circuit, each operating range being defined by thresholds; and
N comparison circuits configured to generate a respective control signal for each of the N additional branches to make the respective switch:
non-conductive when the level of the output node of the amplifier circuit is in the respective operating range; and
conductive when the level of the output node of the amplifier circuit is outside of said respective operating range.

19. The amplification circuit according to claim 18, wherein the resistance value of the feedback loop of the amplifier circuit is controlled to have a second resistance value when said level is between the first threshold and the second threshold.

20. The amplification circuit according to claim 19, wherein the resistance value of the feedback loop of the amplifier circuit is controlled to have a third resistance value when said level is higher than a third threshold, wherein the third threshold is higher than the first threshold, or when said level is lower than a fourth threshold, wherein the fourth threshold is lower than the second threshold.

21. The amplification circuit according to claim 20:
wherein the resistance value of the feedback loop of the amplifier circuit is controlled to have a first resistance value when said level is higher than a first threshold or when said level is lower than a second threshold, where the second threshold is lower than the first threshold; and
wherein the N=1 out-of-saturation operating range is defined between the first threshold and the second threshold and the N=1 branch is formed of a resistive element having a fourth resistance value.
